(19) United States
(12) Patent Application Publication
(10) Pub. No.: US 2015/0069299 A1
(43) Pub. Date: Mar. 12, 2015

(54) Phosphor Ceramics and Methods of Making the Same

(71) Applicant: Nitto Denko Corporation, Osaka (JP)

(72) Inventors: Guang Pan, Carlsbad, CA (US); Jiadong Zhou, San Diego, CA (US); Bin Zhang, San Diego, CA (US); Hiroaki Miyagawa, Oceanside, CA (US)

(21) Appl. No.: 14/483,995

(22) Filed: Sep. 11, 2014

Related U.S. Application Data
(60) Provisional application No. 61/876,652, filed on Sep. 11, 2013.

(51) Int. Cl. C09K 11/77; H01L 33/50

(52) U.S. Cl. CPC C09K 11/7721; H01L 33/502
USPC 252/301.4 H

(57) ABSTRACT

Preparation of a porous ceramic composite with a fluoride phosphor is described herein. The phosphor ceramics prepared may be incorporated into devices such as light-emitting devices, lasers, or for other purposes.

### BACKGROUND

1. Field

The current disclosure describes a composite having a ceramic defining an interconnected porous network and a phosphor material disposed within the porous network.

2. Description of the Related Art

Currently, there are several kinds of red phosphors available such as CaS:Eu²⁺, CaS:Sr²⁺, CASN and K₂SiF₆:Mn⁴⁺. Each of them has advantages and disadvantages. For instance, CaS:Eu²⁺, CaS:Sr²⁺ decomposed in humidity, CASN is stable in humidity but very expensive in terms of processing. Mn⁴⁺ doped K₂SiF₆ (PHFS) is has been known since 1970s as a red fluoride phosphor with sharp emission lines in the range of about 600 to about 700 nm. As it is similar to other inorganic fluoride materials though, K₂SiF₆:Mn⁴⁺ is not stable in high humidity environments.

There have been several attempts to utilize these red phosphors despite these problems. U.S. Pat. No. 7,497,973 B2 and U.S. Patent App. No. 2010/0142189. However, they do not sufficiently mitigate the problem of protecting red emitting fluoride phosphors from degradation due to prolonged exposure to heat and humidity while maintaining the benefits associated with the red fluoride phosphor's preferable emission wavelength.

Generally, warm white light sources with high Color Rendering Index (CRI) are highly desired in lighting applications owing to their ability to give less color distortion. The combination of blue LED and Ce doped Y₃Al₆O₁₂ (YAG) phosphor, however, gives off a cool white with low CRI, e.g., less than 80, due to the lack of red emission in the emission spectra. A phosphor with red emission in the wavelength range of about 600 to about 700 nm can be desired for achieving a light source with high CRI when combined with blue LED.

Thus there is a need for combining a blue LED and Ce doped Y₃Al₅O₁₂ (YAG) phosphor with a suitable red emitting phosphor.

### SUMMARY

Some embodiments include a method for fabricating a phosphor composite comprising: depositing a fluoride phosphor out of a saturated or supersaturated solution of the fluoride phosphor, wherein the solution of the fluoride phosphor is infiltrated within the pores of an interconnected porous ceramic matrix; wherein the interconnected porous ceramic matrix is formed by the annealing and sintering of a porous ceramic preform; and wherein the porous ceramic preform is formed by the sublimation of an organic compound from a ceramic preform comprising the organic compound and at least one ceramic precursor.

In some embodiments a method for fabricating a phosphor composite is provided comprising forming a porous ceramic preform comprising an organic compound and an at least one ceramic precursor; subliming the organic compound from the preform, the sublimation creating an interconnected porous network defined within the preform; sintering the ceramic preform; infiltrating a fluoride phosphor saturated solution within the pores of the interconnected porous network; and depositing the fluoride phosphors out of the saturated solution within the porous network.

In some embodiments, the forming a porous ceramic preform includes dissolving the organic compound in an organic solvent. In some embodiments, the forming a porous ceramic green preform includes crystallizing the dissolved organic compound within a preform matrix. In some embodiments, the porous phosphor ceramic matrix comprises a cerium doped yttrium aluminum garnet, such as (Y₁₋ₓCeₓ)₃Al₅O₁₂, having Ce³⁺ ion concentration, x, in the range of about 0.01 to about 10 at % (atom %). In some embodiments, the organic compound comprises camphene C₁₀H₁₆. In some embodiments, the ceramic preforms are sintered at about 1000° C. to about 2000° C. In some embodiments, the porous phosphor ceramic matrix has a pore volume of about 10 to about 90%. In some embodiments, the porous phosphor ceramic matrix has pore size in the range of about 0.1 to about 1000 μm. In some embodiments, the fluoride phosphor is a phosphor of the chemical formula A₂[MF₆]:Mn⁴⁺, and where A is Li, Na, or K; and M is Ge, Si, Sn, Ti, or Zr. In some embodiments, a phosphor powder is loaded with the organic compound in an amount that is in the range of about 10 to 90 vol %.

In some embodiments, a ceramic composite is provided that is made according the method described above.

In some embodiments, a ceramic composite is provided comprising a porous garnet ceramic, defining a continuous porous network therein; and a phosphor material disposed within said continuous porous network. In some embodiments the phosphor material is a fluoride phosphor. In some embodiments, the porous ceramic comprises Y₃Al₅O₁₂. In some embodiments, the porous ceramic further comprises a dopant material. In some embodiments, the dopant material is Ce3+. In some embodiments, the fluoride phosphor material is selected from A₂[MF₆]:Mn⁴⁺, such that A is selected from Li, Na, and K; and M is selected from Ge, Si, Sn, Ti, and Zr. In some embodiments, the fluoride phosphor material is K₂SiF₆:Mn⁴⁺. In some embodiments, the fluoride phosphor material is disposed within pores of the continuous porous network. Some porous garnet ceramics are luminescent. For some ceramic composites, the fluoride phosphor material has an emissive peak at a higher wavelength than an emissive peak of the porous ceramic garnet. For example, some ceramic garnets may have emission, or emissive peaks in a wavelength range of about 450 nm to about 600 nm, about 500 nm to about 550 nm, or about 530 nm, while some fluoride phosphor material may have emission, or emissive peaks, in a wavelength range of about 600 nm to about 800 nm, about 600 nm to about 700 nm, or about 600 nm to about 650 nm.

### BRIEF DESCRIPTION OF THE DRAWINGS

FIG. 1 is a schematic of an embodiment method described herein.

FIG. 2 is a schematic of an emissive construct embodiment comprising a ceramic matrix with embedded K₂SiF₆:Mn⁴⁺ red phosphor.

FIG. 3 is an SEM image of a cross section of a porous YAG ceramic infiltrated with silicone resin.

FIG. 4 is a schematic of an embodiment of a device comprising an emissive construct and a YAG:Ce³⁺ ceramic.

FIG. 5 is a schematic of an embodiment of a device incorporating a YAG:Ce³⁺ ceramic with embedded K₂SiF₆:Mn⁴⁺ red phosphor as wavelength convertor for a blue LED.

FIG. 6 is an SEM image of the surface morphology of a porous YAG ceramic matrix.

FIG. 7 is an SEM image of a cross section of an example of a porous YAG ceramic with K₂SiF₆:Mn⁴⁺ red phosphor embedded by solvent crashing methods.

FIG. 8 is an EDX analysis of a porous YAG ceramic infiltrated with K₂SiF₆:Mn⁴⁺ red phosphor.

FIG. 9 illustrates the excitation and emission spectra of K₂SiF₆:Mn⁴⁺ and YAG:Ce³⁺ phosphors.

FIG. 10 illustrates the emission spectra of porous YAG ceramics with and without infiltration of K₂SiF₆:Mn⁴⁺ red phosphor.

FIG. 11 illustrates the emission spectra of porous YAG:Ce³⁺ ceramics with and without infiltration of K₂SiF₆:Mn⁴⁺ red phosphor.

### DETAILED DESCRIPTION

In some embodiments, a ceramic composite is provided comprising a porous ceramic comprising a substantially continuous porous network within the ceramic; and a phosphor material disposed within said porous network. In some embodiments, the porous ceramic comprises Y₃Al₅O₁₂. In some embodiments, the porous ceramic further comprises a dopant material. In some embodiments, the dopant material is Ce³⁺. In some embodiments, the ceramic composite comprises a fluoride phosphor material selected from A₂[MF₆]:Mn⁴⁺, such that A is selected from Li, Na, and K; and M is selected from Ge, Si, Sn, Ti, and Zr. In some embodiments, the fluoride phosphor is K₂SiF₆:Mn⁴⁺. In some embodiments, a porous Y₃Al₅O₁₂ or Y₃Al₅O₁₂:Ce³⁺ ceramic can be embedded with K₂SiF₆:Mn⁴⁺ red phosphor affecting improved Color Rendering Index.

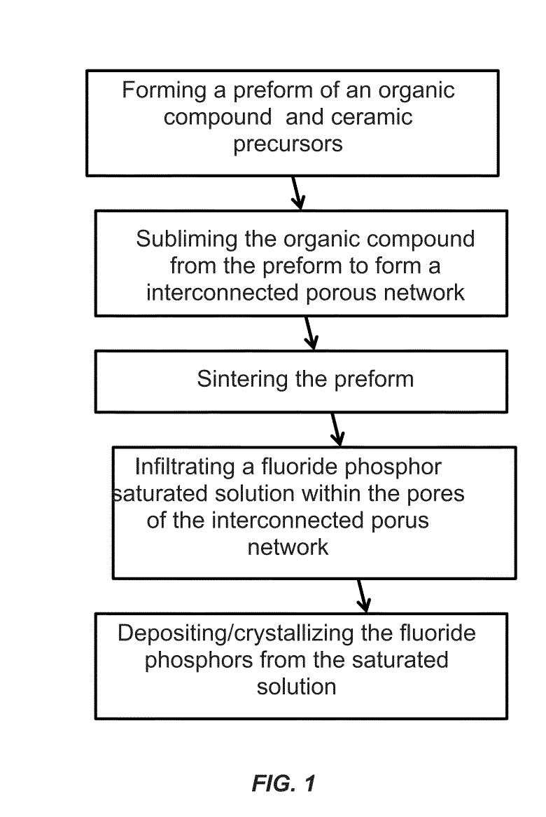

Some embodiments include a method for fabricating a phosphor composite is described comprising forming a porous ceramic preform comprising an organic compound and an at least one ceramic precursor; subliming the organic compound from the preform, the sublimation creating an interconnected porous network defined within the preform; sintering the ceramic preform; infiltrating a fluoride phosphor saturated solution within the pores of the interconnected porous network; and depositing the fluoride phosphors out of the saturated solution within the porous network (see FIG. 1).

In some embodiments, a ceramic precursor can be a multiphase material prepared using generally the same methods used for making translucent sintered ceramic plates. In some embodiments, a ceramic precursor can be yttrium and aluminum precursors, such as Y₂O₃ (yttria) and Al₂O₃ (alumina). In some embodiments, adjusting the ratio of yttrium and aluminum precursors can yield nano-powders comprising YAG and one or more of the following materials: monoclinic Y₄A₁₂O₉ (YAM [yttrium aluminum monoclinic]), hexagonal or orthorhombic YAlO₃ (perovskite or YAP [yttrium aluminum perovskite]), Y₂O₃, or Al₂O₃. In other embodiments, the ceramic precursor material(s) may be introduced and mixed into phosphor nano-powders prior to the sintering step. In some embodiments, precursor powders made by any method, including those that are commercially available, can be mixed in desired stoichiometric amounts prior to the sintering step. For example, when making a ceramic plate with Y₃Al₅O₁₂:Ce³⁺ as the emissive phase, Y₂O₃, Al₂O₃ and CeO₂ powders can be mixed together in a stoichiometric amounts for forming the YAG:Ce phase, and a desired additional amount of Y₂O₃ or Al₂O₃ powders can be added to form the preform.

A phosphor composite can be fabricated from a ceramic preform comprising an organic compound. In some fabrication methods, an organic compound can be sublimed from the preform, which can create an interconnected porous network defined within the preform. In some embodiments, the organic compound is a compound that can sublime. The term sublime, sublimed, subliming or sublimation refers to the change in phase of the material substantially directly from solid to gas. In some embodiments, the subliming organic compound can be a terpene. In some embodiments, the subliming organic compound can be a bicyclic monoterpene. In some embodiments, the subliming organic compound can be 2,2-dimethyl-3-methylene-bicyclo[2.2.1]heptanes (camphene, C₁₀H₁₆). In some embodiments, the compound sublimates or readily volatizes at room temperature. Camphene has a low melting point around 45° C. and readily evaporates at room temperature.

Any amount of the organic compound that can sublime or vaporize to form an interconnected porous network may be used in the ceramic preform. For example, the organic compound can be about 30% to 80%, about 40% to about 80%, or about 50% to about 70% of the weight of both the organic compound and the inorganic ceramic precursors.

In some embodiments, forming the porous ceramic preform includes dissolving the organic compound in an organic solvent. In some embodiments, the organic solvent can be at least one polymeric, organic binder. Possible polymeric, organic binders are, for example, polyvinyl alcohols, polyvinylpyrrolidones, polyvinyl chlorides, polyvinyl acetates, polyvinyl butyrates, polyacrylic acid esters, polyacrylic acid amides, polymethacrylic acid esters, polymethacrylic acid amides, polyacrylonitriles, styrene/acrylic acid ester, vinyl acetate/acrylic acid ester and ethylene/vinyl acetate copolymers, polybutadienes, polyisoprenes, polystyrenes, polyethers, polyesters, polycarbonates, polyurethanes, polyamides, polyimides, polysulfones, melamine/formaldehyde resins, epoxy resins, silicone resins or celluloses. In some embodiments, the binders can be Phthalates, such as, n-Butyl(dibutyl), Dioctyl, butyl enzyl, mixed esters dimethyl; Glycols, such as polyethylene, polyalkylene, polyprolylene, triethylene, dipropylglycol dibenzonate; and others including ethyltoluene sulfonamides, glycerine, tri-butyl-phosphate, butyl stearate, methyl abiete, tricresyl phosphate, propylene carbonate. Other suitable organic solvents include toluene, methyl ethyl ketone (MEK), MEK/anhydrous ethanol, MEK/95% ethanol, xylene/95% ethanol, xylene/anhydrous ethanol, MEK/toluene, MEK/acetone, trichloroethane (TCE), TCE/anhydrous ethanol, TCE/95% ethanol, TCE/MEK/ethanol, TCE/MEK/acetone, toluene/95% ethanol, MEK/95% ethanol/toluene, MEK/methanol/butanol, toluene/ethanol/cyclohexanone, MEK/95% ethanol/cyclohexanone, MEK/ethanol/cyclohexanone, MEK/ethanol/xylene/cyclohexanone and xylene. In some embodiments, the organic solvent can be xylene. In some embodiments, the organic solvent dissolving the organic compound is the same as the organic solvent dispersing or dissolving the ceramic precursor. In some embodiments, dissolving the organic compound, e.g., camphene, instead of melting or fabricating molten organic compound and then cooling the compound could enable the formation of the desired porous network parameters, e.g., size and volume percent, could facilitate the dispersion of the camphene throughout the preform, and/or could enable the manipulation of the organic compound without melting or creating a molten solution of the organic compound.

In some embodiments, the preform can be formed by tape casting. In some embodiments, the forming of the preform includes placing or depositing the solubilized organic compound and at least one ceramic precursor on a substrate surface, and evaporating at least some of the organic solvent from the slurry or mixture. In some embodiments, the substrate surface is a substantially planar and/or open faced casting surface. In some embodiments, the casting can result in a pre-sintered preform having a thickness of between about 100 nm to about 1000 microns. In some embodiments, the pre-sintered preform can have a thickness between about 100 microns to about 500 microns, e.g., about 400 microns. In some embodiments, the evaporation of the solvent as disposed upon the planar surface, can affect a saturation of the organic compound/precursor mixture, leading to crystallization of the organic compound within the mixture slurry or suspension. By crystallizing the organic compound in this way, e.g., by tape cast upon a casting surface, sufficiently rapid sublimation, porosity sized and structural soundness can be affected.

In some embodiments, the porous ceramic comprises a garnet phase with a formula A₃B₅O₁₂. In some embodiments, the porous phosphor ceramic matrix comprises YAG, YAP, YAM, Y₂O₃, and/or Al₂O₃ or any combinations thereof. In some embodiments, the porous ceramic comprises an yttrium aluminum garnet. In some embodiments, the YAG comprises Y₃Al₅O₁₂. In some embodiments, the porous phosphor ceramic comprises a cerium doped yttrium aluminum garnet as (Y₁₋ₓ Ceₓ)₃Al₅O₁₂, having Ce³⁺ ion concentration, x, in the range of about 0.01 to about 10 at %. In some embodiments, the ion concentration ranges from about 0.01 to about 0.1 at %, about 0.1 to about 1 at %, or about 1 to about 10 at %. In some embodiments, the porous (Y₁₋ₓCeₓ)₃Al₅O₁₂ ceramic matrix has emission in the wavelength range of about 480 to about 750 nm with peak wavelength (e.g., a wavelength where a relative maximum in the spectrum occurs) or average wavelength (e.g. a wavelength that is the average or mean of the visible emission) in the range of about 520 to about 550 nm under irradiation of violet or blue light in the wavelength range of about 400 to about 480 nm.

In some embodiments, the porous ceramics comprise YAG, YAP, YAM, Y₂O₃, or Al₂O₃. The combination of blue LED and Ce doped Y₃Al₅O₁₂ (YAG) phosphor, can provide a cool white light with low CRI, e.g., less than 80, due to the lack of red emission in the emission spectra.

In some embodiments, the method can comprise infiltrating a fluoride phosphor within the continuous porous network defined within the ceramic preform. In some embodiments, the method can comprise depositing the fluoride phosphors within the pores. In some embodiments, the depositing can be by crystallizing or recrystallizing the dissolved fluoride phosphor in the continuous porous network. In some embodiments, the phosphor composition comprises at least one of A₂[MF₆]:Mn⁴⁺, and where A is selected from Li, Na, and K, and M is selected from Ge, Si, Sn, Ti, and Zr, and combinations thereof. Suitable phosphorous compounds can be those described in co-pending applications PCT application, No. PCT/US13/30539, filed Mar. 12, 2013, PCT/US13/37247, filed Apr. 18, 2013, and U.S. patent application Ser. No. 13/865,9567 filed Apr. 18, 2013, which are incorporated by reference in their entirety for their description of red emitting phosphor compounds. In one embodiment, the phosphor composition is K₂SiF₆:Mn⁴⁺, and is embedded within the porous ceramic matrix. While not wanting to be limited by theory, it is believed that this embedding can protect the fluoride phosphors, which are generally unstable in high humidity, and/or can increase the maximum operating temperature that the fluoride phosphors can withstand. In some embodiments, the fluoride phosphors decompose at a temperature greater than 800 C. In some embodiments, the fluoride phosphors lose at least 50% activity, 60% activity, 70% activity, 80% activity within at least one hour at a temperature of at least 500 C, 600 C, 700 C, and/or 800 C.

A method for fabricating a phosphor composite is provided by forming an unsintered ceramic preform containing an organic compound and a phosphor powder. In some embodiments, the unsintered ceramic preform is sintered to form a porous phosphor ceramic matrix, the ceramic matrix comprising a continuous network of pores within the phosphor ceramic matrix, and having emission lines in the wavelength range of about 300 to about 500 nm. In some embodiments, CRI can be further increased in an LED application where fabricating the phosphor composite includes diffusing a fluoride phosphor with emission lines different from the porous phosphor ceramic matrix within the pores of said matrix and then recrystallizing the fluoride phosphor within said pores.

In some embodiments, the phosphor materials may be chosen so that the composite of ceramic and the phosphor within the pores of the ceramic give rise to a color rendering index (CRI) greater than about 80 when irradiated with a light source having a peak wavelength or average wavelength of about 440 to about 480 nm. In some embodiments, the ceramic matrix has emission lines in the wavelength range of about 300 to about 500 nm.

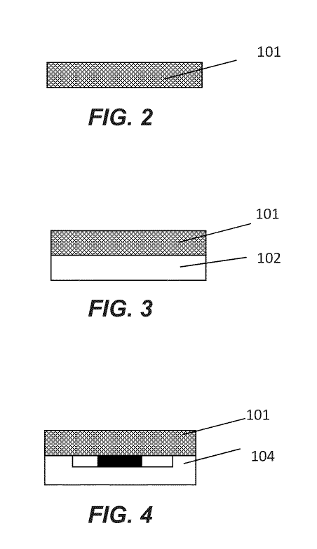

In some embodiments, the emissive construct may comprise an emissive garment material and an emissive PHFS material (FIG. 2). Thus, porous YAG ceramics may thus be used as an emitting, protective shield to surround the desirable PHFS. The YAG ceramic either with or without cerium dopant can be prepared by using an organic material as a template. In one embodiment, the method comprises the step of adding a subliming organic compound to a slurry of the ceramic precursor. In some embodiments, the subliming organic compound can be a terpene. In some embodiments, the subliming organic compound can be a bicyclic monoterpene. In some embodiments, the subliming organic compound can be camphene. In some embodiments, the compound sublimes at about 20-30° C., e.g. room temperature. In one embodiment, the organic material used is a compound. In one embodiment, this compound may be camphene, C₁₀H₁₆. Camphene has a low melting point around 45° C. and readily evaporates at room temperature. Using camphene may allow the ultimate pore size and density of the porous ceramic matrix to be selectively manufactured by treating the camphene to different temperatures while mixing with the phosphor powder or ceramic precursors. In some embodiments, use of camphene as the organic compound could facilitate the protection of the mechanical integrity of the ultimate porous phosphor ceramic matrix. Use of camphene may also avoid prolonged exposure to high temperatures during fabrication. Unnecessarily long exposure to high temperatures may compromise the tensile strength, luminosity or emission wavelength of the porous phosphor ceramic matrix. As such, camphene may be useful In light of its high volatility in relatively low temperatures and ease of vaporization.

In some embodiments, the ceramic matrix has a pore volume of about 10 to about 90%. In some embodiments, the ceramic matrix has a pore volume of about 10 to about 30%, 20 to about 90 vol %, about 20 to about 50%, about 30 to about 60%, about 40 to about 70%, about 50 to about 80%, or about 60 to about 90%. In some embodiments, the ceramic matrix has a pore volume of about 60 to about 80 vol %. In some embodiments, pores sized in the range of about 0.1 to about 1000 μm ensure tensile strength. In some embodiments, pore sizes range from about 0.1 to about 1 μm, about 1 to about 10 μm, about 10 to about 100 μm, or about 100 to about 1000 μm. In some embodiments, the ceramic matrix contains pores of size ranging from about 10 to about 100 μm. Pore size can be adjusted in the range of about 2 μm to about 100 μm by varying the substrate temperature and amount of camphene loading. In some embodiments, pore size can be about 2 to about 10 μm, about 10 to about 50 μm, or about 50 to about 100 μm.

In some embodiments, the method of making a ceramic composite comprises forming an unsintered ceramic preform with an organic compound and a phosphor powder. In some embodiments, forming an unsintered ceramic perform includes preparing a slurry containing ceramic precursors. In some embodiments, the ceramic precursors are those required to provide a ceramic perform or green sheet. Suitable compounds for the forming of a ceramic precursor include those described in U.S. Pat. No. 8,169,136 and U.S. Pat. No. 8,283,843, which are incorporated by reference in their entirety for their description of ceramic matrix precursors.

In some embodiments, the organic compound sublimates out of the preformed green sheet at a temperature of at least 0° C., at least 10° C., at least 20° C., at least room temperature. In one embodiment, the unsintered preform of a porous YAG ceramic includes an interconnected network of pores within the preform, wherein at least a portion of the pores connect to provide at least one passageway from one side to the other side of the ceramic. This continuous and substantially open microstructure allows a material introduced therein to intercommunicate throughout the network such that substantially uniform dispersion of said material throughout the network may be achieved. In some embodiments, this enables substantially scattered placement of introduced phosphor material throughout the ceramic matrix. In this manner, substantially even red emission can be achieved. In one embodiment, the material introduced within the pores is red phosphor crystals. The crystals can intercommunicate throughout the pores, becoming substantially scattered and regrow in such a manner therein. A bicontinuous microstructure is shown in FIG. 3 and illustrates the interconnected nature of the networks that allows the substantially free flow of materials introduced therein. Interconnected nature of the network of pores therein may aid substantial dispersal of the phosphor materials introduced therein. This further facilitates protecting phosphor ceramics from the humidity and high operating temperatures that cause them to degrade quickly.

In some embodiments, the ceramic matrix defines a continuous porous network whose volume may be selectively manufactured so that the materials intended for embedding within the matrix may be able to flow substantially throughout the continuous network. In some embodiments, the materials intended for embedding can be phosphor materials for recrystallization. In some embodiments, the ceramic matrix is further infiltrated with resin and other polymeric materials. In some embodiments, the further infiltration can create a substantially void-free composite if such polymers or polymeric materials have a refractive index between the matrix phosphor ceramic and embedded complex fluoride phosphor to reduce the scattering of light.

In some embodiments, method comprises heating the preform to a temperature less than the debindering and/or sintering temperatures to laminate plural preforms into a thicker preform. In some embodiments, the plural preforms laminated into a thicker preform range, for example, from about 2 preforms, about 3 preforms, about 4 preforms, about 5 preforms, about 7 preforms, to about 10 preforms. In some embodiments, the preforms are heated to a temperature ranging from about 300° C. to about 900° C. In some embodiments, the preforms are laminated at temperatures ranging from about 40° C., from about 50° C., from about 60° C., to about 70° C., to about 80° C., to about 90° C., to about 100° C., or any combination of the aforementioned range temperatures. In some embodiments, the preforms are laminated at temperatures ranging from about 70° C. to about 90° C., e.g., about 80° C.

In some embodiments, method comprises heating the preform to a temperature less than the sintering temperature to remove or evaporate any organic solvents and/or binders used to form the preform. In some embodiments, the preforms are heated to a temperature ranging from about 300° C. to about 900° C. In some embodiments, the preforms can be debindered in temperatures of at least about at least 300° C., at least about 400° C., or at least about 500° C.; and/or up to about 600° C., up to about 700° C., up to about 800° C., up to about 850° C., up to about 900° C., or up to about 950° C., or any combination of the aforementioned range temperatures.

In some embodiments, annealing can be performed on the preform after debindering is performed. Annealing includes heating the material to convert some or all of the material to the desired phase. For example, annealing may be used to convert non-garnet phases comprising Y, Al, and O into yttrium aluminum garnet. In some embodiments, the preform can be annealed in temperatures of at least about 450° C., at least about 1200° C., at least about 1400° C.; and/or up to about 1500° C., up to about 1600° C., up to about 1700° C., up to about 1750° C., up to about 1800° C., up to about 1900° C., or at about 1350° C., or at about 1500° C., or any temperature bounded by or between any of these values.

In some embodiments, the rate of heating when annealing the preform, can be done at a heating rate of about 0.1° C./min to about 5° C./min, from about 0.5° C./min to about 2° C./min, or about 1° C./min, or any rate bounded by or between any of these values.

In some embodiments, the pressure at which the annealing is performed can be from about 0 Torr to about 1000 Torr, from about 0.001 Torr to about 50 Torr, or about 20 Torr, or any pressure bounded by or between any of these values. In some embodiments, annealing can be performed in a vacuum.

In some embodiments, the time at which annealing is performed on the preform can be from about 1 hour to about 24 hours, from about 2 hours to about 8 hours, or about 5 hours, or any amount of time bounded by or between any of these values.

In some embodiments, the method can comprise sintering the ceramic preform to form a single ceramic piece from a powder or from smaller solid particles. Sintering is a process in which particles are joined together through atomic diffusion by subjecting a material to temperatures below the melting point of its constituent particles. In some embodiments, the sintering combines a ceramic precursor into a ceramic compound. In some embodiments, the sintering of YAP, YAM, Y₂O₃, or Al₂O₃ forms a ceramic comprising the yttrium garnet previously described. In some embodiments, a sintering process will produce porous YAG ceramics with porosity up to at least 90 vol % and sufficient mechanical strength. In some embodiments, the porous YAG ceramics have porosity of up to about 10%, up to about 20%, up to about 30%, up to about 40%, up to about 50%, up to about 60%, up to about 70%, up to about 80%, up to about 90%, or up to about 95%.

In some embodiments, the sintering is performed under an ambient atmosphere. In some embodiments, the sintering can be performed under a non-oxidizing atmosphere. In some embodiments, the non-oxidizing atmosphere can be an inert gas. In some embodiments, the inert gas can be argon or nitrogen (N₂). In some embodiments, the non-oxidizing atmosphere can be a reducing atmosphere. In some embodiments, the reducing atmosphere can be N₂/H₂, wherein the ratio of N₂ to H₂ can be from about 100:1 by volume (N₂ to H₂) to about 2:1 (N₂ to H₂) by volume. In some embodiments, the atmosphere can be performed under an oxidizing atmosphere. In some embodiments, the oxidizing atmosphere can be a “wet” N₂/O₂ atmosphere, such as air having an amount of water which could naturally be present.

In some embodiments, the sintering at a temperature that is sufficiently high as to evaporate the organic solvent, form the yttrium preform, but sufficiently low as to avoid compromising the mechanical integrity of the ceramic material. In an embodiment, the preforms are sintered in temperatures ranging from about 1000° C. to about 2000° C. In some embodiments, the preforms are sintered in temperatures ranging from about 1000° C., from about 1200° C., from about 1400° C., to about 1400° C., to about 1500° C., to about 1600° C., to about 1800° C., 10 about 1900° C. to about 1950° C. to about 2000° C. or any combination of the aforementioned range temperatures. In some embodiments, the preforms are sintered in temperatures ranging from about 1700 to about 1900° C., e.g., about 1800° C. In some embodiments, the rate of heating when sintering the preform, can be done at a heating rate of about 0.1° C./min to about 5° C./min, from about 0.5° C./min to about 2° C./min, or about 1° C./min, or any rate bounded by or between any of these values.

In some embodiments, the pressure at which the sintering is performed can from about 0 Torr to about 1000 Torr, from about 0.001 Torr to about 50 Torr, or about 20 Torr, or any pressure bounded by or between any of these values. In some embodiments, sintering can be performed in a vacuum.

In some embodiments, the time at which sintering is performed on the preform can be from about 1 hour to about 24 hours, from about 2 hours to about 8 hours, or about 5 hours, or any amount of time bounded by or between any of these values.

In some embodiments, the rate of cooling when sintering the preform, can be done at a cooling rate of about 0.1° C./min to about 20° C./min, from about 0.5° C./min to about 15° C./min, or about 10° C./min, or any cooling rate bounded by or between any of these values.

In some embodiments, the method can comprise infiltrating a phosphorous compound within the continuous porous network defined within the ceramic preform. In some embodiments, an infiltration solution comprises a carrier material and the phosphorous compound. In some embodiments, as described earlier, the phosphorous compound can be K₂MnF₆. In some embodiments, the phosphor can comprise phosphor precursors. In some embodiments, the phosphor precursors can be K₂SiF₆ (Aldrich), K₂MnF₆ and/or K₂SiF₆:Mn⁴⁺. Suitable other phosphor precursors are described in PCT application, No. PCT/US13/30539, filed Mar. 12, 2013, PCT/US13/37247, filed Apr. 18, 2013, and U.S. patent application Ser. No. 13/865,9567 filed Apr. 18, 2013, which are incorporated by reference in their entirety for their description of red emitting phosphor compounds. In one embodiment, the carrier material is a strong acid sufficient to dissolve the insoluble precursors. In one embodiment, the strong acid is HF. In some embodiments, the strong acid is at least a 1 N solution of acid. In one embodiment, the strong acid is about 48% to about 51% HF. HF is additionally beneficial because no additional impurities are introduced into the fluoride phosphor compound.

In some embodiments, the method can comprise depositing the fluoride phosphors out of the a solution, such as a saturated or supersaturated solution, within the porous network. In some embodiments, the method can comprise recrystallizing the fluoride phosphor within the pores or generated porous network defined within the ceramic matrix. In one embodiment, the K₂SiF₆:Mn⁴⁺ red phosphors to be introduced into the porous phosphor ceramic matrix can be prepared through processes such as recrystallization, solvent crashing, etc. Solid solution crystalline of K₂SiF₆:Mn⁴⁺ will precipitate when the solution mixture becomes saturated or supersaturated, for example by evaporation of solvents as HF in which the precursors are dissolved, and/or addition of additional solvent in which the precursor has a poor solubility. Mn⁴⁺ ion as an activator in the K₂SiF₆ lattice gives sharp red emission lines in the wavelength range of about 600 to about 650 nm. In some embodiments, the additional solvent can be acetone.

Phosphor particles can be generated by re-crystallization methods wherein solid precursors are dissolved and the desired phosphor particles are recrystallized under selected environmental conditions. In some embodiments, the method comprises creating a supersaturated solution of the desired phosphor. In some embodiments, to create a supersaturated solution, the solution of K₂SiF₆, K₂MnF₆ in HF is heated to about 90° C. for about 10-30 minutes. The heated solution is then cooled down to room temperature and the crystallizing of the red phosphor begins when the solution is cooled. In some embodiments, K₂SiF₆, a commercial product, and K₂MnF₆ are dissolved in HF according to a ratio that enables doping of Mn⁴⁺ in K₂SiF₆ to take place (the Mn⁴⁺ doping ratio in K₂SiF₆:Mn⁴⁺). In some embodiments, the molar ratio of K₂SiF₆, to K₂MnF₆ can be between about 5 to about 20 moles of K₂SiF₆, to about 1 mole of K₂MnF₆. In one embodiment, for example, the molar ratio is about 6 to about 15 moles, e.g., about 9:1 K₂SiF₆ to K₂MnF₆. HF can be used since the phosphor materials may contain fluoride (F), and degrade easily when subjected to the influence of humidity or organic materials.

The infiltration of the phosphor material into or within the continuous porous network can be by infiltrating a supersaturated solution and subsequent precipitation or crystallization of the phosphor from such a supersaturated solution. The supersaturated state can be achieved by any of the following methods: evaporation of HF, addition of poor solvent, or cooling. The resulting K₂SiF₆:Mn⁴⁺, can then be recrystallized out of the supersaturated solution within the continuous porous network.

In some embodiments, an intermediate K₂MnF₆ is prepared for use in the recrystallization method. In some embodiments, K₂MnF₆ is produced according to published method (1953 Angew. Chem. 65: 304).

In some embodiments, the supersaturated HF solution of K₂SiF₆ and K₂MnF₆ is obtained by evaporation of the HF solution. In some embodiments, the solution where K₂SiF₆ and K₂MnF₆ is dissolved in HF according to one ratio and heated to a temperature below the boiling point of HF (which is about 110° C.), so the solution can be heated to about 90° C. K₂SiF₆:Mn⁴⁺ crystals produced this way within the ceramic matrix typically have an average diameter between about 200 and about 500 μm.

In some embodiments, the supersaturated HF solution of K₂SiF₆ and K₂MnF₆ is obtained by adding a miscible solvent which is characterized by poor solubility for PHFS. In some embodiments, the miscible solvent can be acetone, methanol, ethanol, and/or acetonitrile. In one embodiment, K₂SiF₆:Mn⁴⁺ produced this way had pore size ranging from about 200 nm to about 5 μm.

In some embodiments, the supersaturated HF solution of K₂SiF₆ and K₂MnF₆ is obtained by heating the solution followed by cooling in an ice bath. In some embodiments, the solution is heated to a temperature of at least about 40° C., about 50° C., about 60° C., about 70° C., about 80° C. and/or about 90° C. (below the boiling point of HF). In one embodiment, K₂SiF₆:Mn⁴⁺ produced this way has a pore size ranging from about 30 to about 100 μm.

In some embodiments, growing K₂SiF₆:Mn⁴⁺ red phosphors inside porous YAG ceramics can be realized by infiltrating or impregnating the porous ceramics matrix and then adding additional poor solvent or evaporating HF.

In one embodiment, a ceramic compact is described, comprising phosphor composition having a degradation temperature of less than about 800° C. Degradation temperature includes, for example, and is not limited to decomposition or melting temperatures. Decomposition temperature refers to the temperature at which the composition's chemical bonds are broken in the presence of heat. Decomposition temperature is the temperature at which thermal decomposition occurs, which differs for different compounds. Decomposition temperature can be determined by various physical analytical methods, e.g., TGA. In some embodiments, for example with K₂SiF₆ (PHFS), the decomposition temperature can be about 550° C. In some embodiments, the phosphor composition has a decomposition temperature of less than about 800° C., of less than about 700° C., less than about 650° C., less than about 600° C., less than about 550° C., or less than about 500° C. Melting temperature refers to the temperature at which the solids change into a different phase, e.g., gas or liquid. In some embodiments, for the case of K₂TiF₆, its melting temperature is about 780° C. For both cases of K₂SiF₆ and K₂TiF₆, which have either decomposition or melting temperature lower than about 800° C., they cannot be sintered by conventional methods such as vacuum heating.

In some embodiments, the method of manufacturing a phosphor composite further comprises infiltrating the continuous porous network with a polymeric material and the red fluoride phosphor. In some embodiments, the red phosphor material K₂SiF₆:Mn⁴⁺ is mixed with a silicone elastomer. This resultant phosphor elastomer suspension is then infiltrated into the sintered porous ceramic, e.g., YAG. In some embodiments, the polymeric material can be silicone resins, silicone elastomers, silicone modified resins, UV curable resin, acrylic resin, epoxy and phenolic resin, polyester resins, polyisocyanate resins, polyurethane resins, amino resins. In some embodiments, a suspension containing fluoride red phosphors can be infiltrated into the preform porous network, the suspension comprising sol-gels formed by hydrolysis of orthosilicates, for example Tetraethylorthosilicate (TEOS). The suspension can also comprise sodium metasilicate, known as liquid glass.

FIG. 4 shows an embodiment of a YAG:Ce³⁺ ceramic 102 in optical communication with, e.g. disposed below an emissive construct 101 of porous YAG ceramic with embedded K₂SiF₆:Mn⁴⁺ red phosphor.

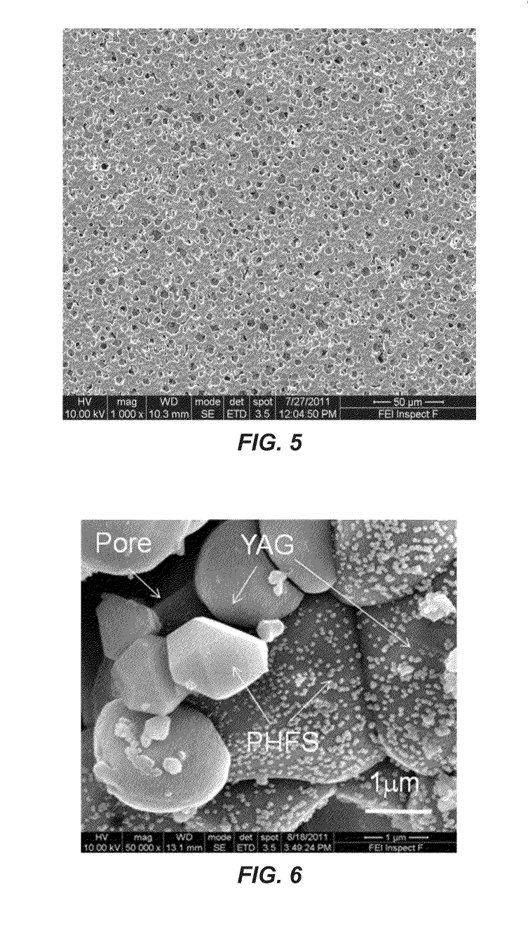

FIG. 5 shows an example of one way that a phosphor ceramic may be integrated into an LED. A phosphor emissive construct 101 may be disposed above a light-emitting diode 104 so that light from the LED passes through the phosphor ceramic before leaving the system. Part of the light emitted from the LED may be absorbed by the phosphor ceramic and subsequently converted to light of a lower wavelength by luminescent emission. Thus, the color of light-emitted by the LED may be modified by a phosphor ceramic such as phosphor ceramic 101.

The following non-limiting embodiments are contemplated:

### Embodiment 1

A method for fabricating a phosphor composite comprising: forming a porous ceramic preform comprising an organic compound and an at least one ceramic precursor;

subliming the organic compound from the preform, the sublimation creating an interconnected porous network defined within the preform;

sintering the ceramic preform;

infiltrating a fluoride phosphor saturated solution within the pores of the interconnected porous network; and

depositing the fluoride phosphors out of the saturated solution within the porous network.

### Embodiment 2

The method of embodiment 1, wherein the forming a porous ceramic preform includes dissolving the organic compound in an organic solvent.

### Embodiment 3

The method of embodiment 2, wherein the forming a porous ceramic green preform includes crystallizing the dissolved organic compound within the preform.

### Embodiment 4

The method according to Embodiment 3, wherein the preform comprises a cerium doped yttrium aluminum garnet as (Y₁₋ₓCeₓ)₃Al₅O₁₂, having Ce³⁺ ion concentration, x, in the range of about 0.01 to about 10 at %.

### Embodiment 5

The method according to Embodiment 1, wherein the organic compound comprises camphene C₁₀H₁₆.

### Embodiment 6

The method according to embodiment 1, wherein the ceramic preforms are sintered at about 1000° C. to about 2000° C.

### Embodiment 7

The method according to Embodiment 1, wherein the porous phosphor ceramic matrix has a pore volume of about 10 to about 90%.

### Embodiment 8

The method according to Embodiment 1, wherein the porous phosphor ceramic matrix has pore size in the range of about 0.1 to about 1000 μm.

### Embodiment 9

The method according to Embodiment 1, wherein the fluoride phosphor is a phosphor of the chemical formula A₂[MF₆]:Mn⁴⁺, and where A is selected from Li, Na, and K; and M is selected from Ge, Si, Sn, Ti, and Zr.

### Embodiment 10

The method according Embodiment 1 wherein the phosphor powder is loaded with the organic compound in an amount that is in the range of about 10 to 90 vol %.

### Embodiment 12

A ceramic composite made according to embodiments 1-11 above.

### Embodiment 13

A ceramic composite comprising:

a porous garnet ceramic, defining a continuous porous network therein; and

a fluoride phosphor material disposed within said continuous porous network.

### Embodiment 14

The ceramic composite of embodiment 13, wherein the porous ceramic comprises Y₃Al₆O₁₂.

### Embodiment 15

The ceramic composite of embodiment 13, wherein the porous ceramic further comprises a dopant material.

### Embodiment 16

The ceramic composite of embodiment 15, wherein the dopant material is Ce³⁺.

### Embodiment 17

The ceramic composite of embodiment 16, wherein the fluoride phosphor material is selected from A₂[MF₆]:Mn⁴⁺, such that A is selected from Li, Na, and K; and M is selected from Ge, Si, Sn, Ti, and Zr, is K₂SiF₆:Mn⁴⁺.

### Embodiment 18

The ceramic composite of embodiment 13, 14, 15, 16, or 17, wherein the fluoride phosphor material is disposed within pores of the continuous porous network.

### Embodiment 19

The ceramic composite of embodiment 13, 14, 15, 16, 17, or 18, wherein the porous garnet ceramic is luminescent.

### Embodiment 20

The ceramic composite of embodiment 19, wherein the fluoride phosphor material has an emissive peak at a higher wavelength than an emissive peak of the porous ceramic garnet.

### EXAMPLES

### Example 1

A 50 ml high purity Al₂O₃ ball mill jar was filled with 55 g of Y₂O₃-stabilized ZrO₂ balls having a 3 mm diameter. In a 20 ml glass vial, 0.153 g dispersant (Flowlen G-700. Kyoeisha), 2 ml xylene (Fisher Scientific, Laboratory grade) and 2 ml ethanol (Fisher Scientific, reagent alcohol) were mixed until the dispersant was dissolved completely. The dispersant solution and sintering aid tetraethoxysilane (TEOS) (0.038 g, Fluka) were added to a ball mill jar.

Y₂O₃ powder (3.984 g, 99.99%, lot N-YT4CP, Nippon Yttrium Company Ltd.) with a BET surface area of 4.6 m²/g and Al₂O₃ powder (2.998 g, 99.99%, grade AKP-30, Sumitomo Chemicals Company Ltd.) with a BET surface area of 6.6 m²/g were added to a ball mill jar. The total powder weight was 7.0 g and the ratio of Y₂O₃ to Al₂O₃ was at a stoichiometric ratio of 3:5. A first slurry was produced by mixing the Y₂O₃ powder, the Al₂O₃ powder, dispersant, tetraethoxysilane, xylenes, and ethanol by ball milling for about 24 hours.

A solution of binders and plasticizers was prepared by dissolving 3.5 g poly(vinyl butyral-co-vinyl alcohol-co-vinyl acetate) (Sigma-Aldrich, St. Louis, Mo., USA), 1.8 g benzyl n-butyl phthalate (98%, Alfa Aesar), and 1.8 g polyethylene glycol (Mn=400, Sigma-Aldrich) in 12 ml xylene (Fisher Scientific, Laboratory grade) and 12 ml ethanol (Fisher Scientific, reagent alcohol). A second slurry was produced by adding 4 g of the binder solution into the first slurry and then milling for about another 24 hours. When ball milling was complete, the second slurry was passed through a syringe-aided metal screen filter with pore size of 0.05 mm. The viscosity of the second slurry was adjusted to 400 centipoise (cP) by evaporating solvents in the slurry while stirring at room temperature.

A 50 ml high purity Al₂O₃ ball mill jar was filled with 10 g secondary slurry and 20 g Y₂O₃— stabilized ZrO₂ balls having a 3 mm diameter and then 4.0 g camphene (Alfa Aesar, 97%) was added to the slurry. The mixture was ball-milled for about 2 hours to form a third slurry loaded with camphene. The slurry was then cast on a releasing substrate, e.g., silicone coated Mylar® carrier substrate (Tape Casting Warehouse) with an adjustable film applicator (Paul N. Gardner Company, Inc.) at a cast rate of 30 cm/min. The blade gap on the film applicator was set at 0.381 mm (15 mil). The cast tape was dried overnight at ambient atmosphere to produce a porous green sheet of about 100 μm thickness.

The porous green sheet was cut into circular shape of 13 mm in diameter and placed between circular dies with mirror-polished surfaces and heated on a hot plate to 80° C., followed by compression in a hydraulic press at a uniaxial pressure of 5 metric tons and held at that pressure for 5 minutes.

For debindering, laminated green sheets were sandwiched between ZrO₂ cover plates (1 mm in thickness, grade 42510-X, ESL Electroscience Inc.) and placed on an Al₂O₃ plate of 5 mm thickness. They were then heated in a tube furnace in air at a ramp rate of 0.5° C./min to 800° C. and held for 2 hours to remove the organic components (debinder) from the green sheets.

After debindering, the assembly was annealed at about 1500° C. at 20 Torr for about 5 hours at a heating rate of 1° C./min to complete conversion from non-garnet phases of Y—Al—O in the non-emissive layer, including, but not limited to, amorphous yttrium oxides, YAP, YAM or Y₂O₃ and Al₂O₃ to yttrium aluminum garnet (YAG) phase and increase the final YAG grain size. Following the first annealing, the assembly were further sintered in a vacuum of 10⁻³ Torrat about 1800° C. for 5 hours at a heating rate of 5° C./min and a cooling rate of 10° C./min to room temperature to produce a porous YAG ceramic sheet of about 0.4 mm thickness. The porous YAG ceramic sheets have a pore volume estimated as 70 vol % and pore size around 5 μm average diameter (FIG. 6). SEM images of cross section of porous YAG ceramics infiltrated with silicone resin in FIG. 3 indicated that porous YAG ceramic grains and pores form a continuous network extending from one side of the ceramic sheet to the opposite side.

30.0 g KHF₂ (vendor,) 1.5 g K₂MnO₄ (vendor) and 100 ml of 20 ml hydrofluoric acid (HF, 48-51%, Sigma-Aldrich) were mixed and stirred to completely dissolve the solids in the HF. Hydrogen peroxide (H₂O₂) was added dropwise to the solution until the solution turned yellow. The resulting dispersion was filtered and rinsed with acetone and dried to provide a yellow precipitate (K₂MnF₆) confirmed by XRD.

An infiltration solution was prepared by mixing 500 mg potassium hexafluorosilicate (K₂SiF₆, 99.0%,Fluka) with 62.5 mg potassium hexafluoromanganate (K₂MnF₆) and 20 ml hydrofluoric acid (HF, 48-51%, Sigma-Aldrich). The mixture was stirred at room temperature for about 20 min until a complete dissolving of solids was seen.

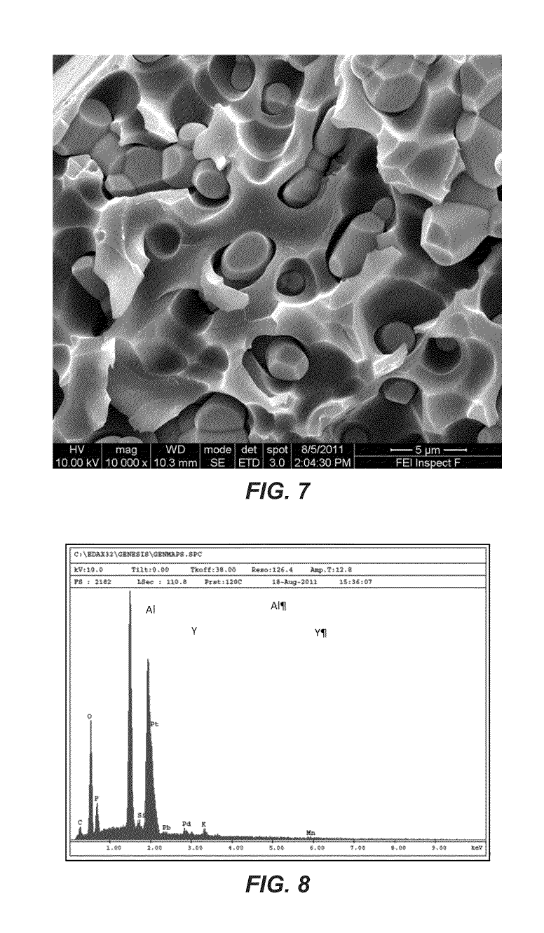

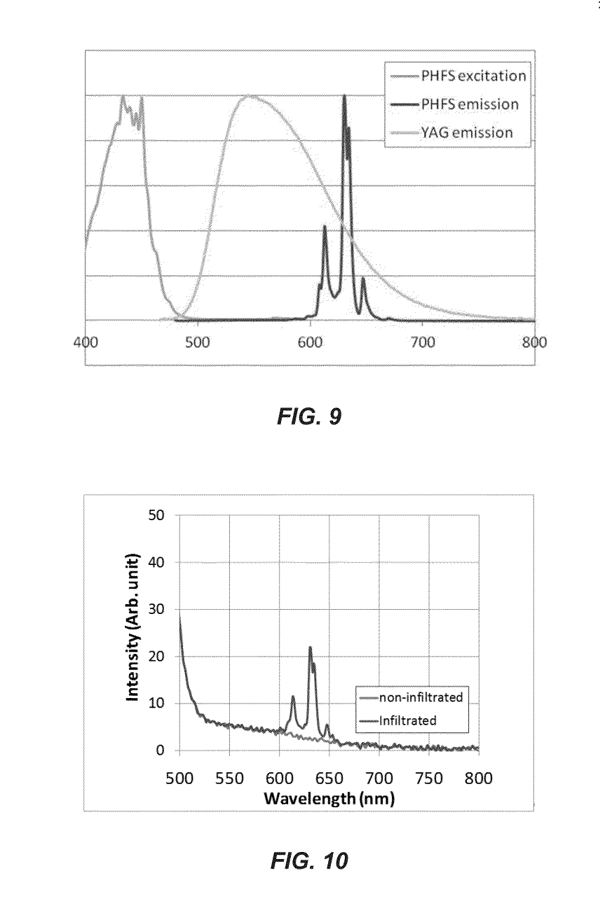

Porous YAG ceramic pieces of 12 mm in diameter were placed in a 50 ml Teflon beaker. The infiltration solution was then added to the beaker until the porous ceramics were immersed completely in the solution. After holding the immersed ceramic pieces in solution for about 2 hours to let the solution infiltrate the pores, extra solution was removed by polypropylene pipette and then about 10 ml acetone was added drop wise into the beaker and held for about 30 min. The infiltrated porous ceramics were rinsed with acetone repeatedly until the acetone rinse pH reached 7.0. After removing extra acetone, the infiltrated porous ceramics were dried at ambient atmosphere by evaporating residual acetone in pores at room temperature. SEM cross section image (FIG. 7) showed the K₂SiF₆:Mn⁴⁺ crystalline formed on surface of YAG grain with size around 40 nm and in pores with size greater than 1 μm, which was confirmed by EDX analysis (FIG. 8).

In some experiments, acetonitrile, methanol (MeOH) or ethanol were added dropwise into the K₂MnF₆/K₂SiF₆ HF solution. In some experiments, the K₂MnF₆/K₂SiF₆ HF solution was heated to about 9° C. for about 20 minutes. The heated clear solution was then placed in an ice cooled bath for about 1.5 hours, then rinsed in acetone and dried.

### Example 2

Comparison samples were prepared in accordance to Example (1) except with no infiltration of K₂SiF₆:Mn⁴⁺ solution.

### Example 3

YAG:Ce precursors with Ce content of 1.5 at % synthesized by plasma was annealed at 1350° C. for 2 hours in tube furnace in reducing atmosphere containing 3% of H₂ and 97% of N₂. Surface area of annealed powder precursors showed value of 4.0 m²/g. Yttrium aluminum garnet phase was confirmed by X-ray diffraction. 10 gram of YAG:Ce³⁺ powders was mixed 0.3 gram surfactant (KD-4 hypermer, Croda) and 15 gram camphene (Alfa Aesar, 97%) in a 240 ml PTFE jar at 60° C. with stirring for 24 hours in oven to form a slurry. The obtained slurry was cast into circular shape of 13 mm in diameter onto a Mylar substrate with silicone coating. The cast pieces were kept in ambient atmosphere overnight to let camphene evaporate. Following that, the cast pieces were calcinated in the tube furnace at 1500° C. in air for 5 hours at a heating and cooling ramp of 5° C./min. Second sintering of the cast pieces was performed in a vacuum furnace (M-60 Centro, USA) in vacuum of 10⁻³ Torr. Porous ceramic matrices with pore size around 40 μm were obtained.

Porous YAG:Ce³⁺ ceramics piece of 12 mm in diameter were placed in a 50 ml Teflon beaker and then infiltration solution was added to the beaker until porous ceramics was immersed completely by the solution. After holding for 2 hours to let solution infiltrate into the pores, extra solution was removed by polypropylene pipette.

The infiltrated YAG:Ce³⁺ ceramics were kept in ambient atmosphere overnight to let residual HF in pores evaporate.

### Example 4

Comparison samples were prepared in accordance to Example (3) except with no infiltration of K₂SiF₆:Mn⁴⁺ solution.

### Example 5

IQE and PL spectra measurements were performed with an Otsuka Electronics MCPD 7000 multi channel photo detector system (Osaka, JPN) together with required optical components such as integrating spheres, light sources, monochromator, optical fibers, and sample holder as described below.

The porous YAG:Ce phosphor ceramics plate constructed as described above, with a diameter of about 11 mm, were placed on a light emitting diode (LED) with peak wavelength or average wavelength at 455 nm with acrylic lens which had a refractive index of about 1.45. An LED with YAG:Ce was set up inside integration sphere. The YAG:Ce ceramic plate was irradiated by the LED and the optical radiation of blue LED and YAG:Ce ceramic were recorded respectively. Next, the YAG:Ce ceramic plate was removed from LED, and then the radiation of blue LED with the acrylic lens was measured.

PL spectra of porous YAG infiltrated with K₂SiF₆:Mn⁴⁺ showed clearly the feature emission lines of K₂SiF₆:Mn⁴⁺ in the wavelength range of 600 to 650 nm. In comparison, no feature emission lines were observed in the comparison samples achieved with a porous YAG ceramic plate without infiltration (FIG. 10).

### Example 6

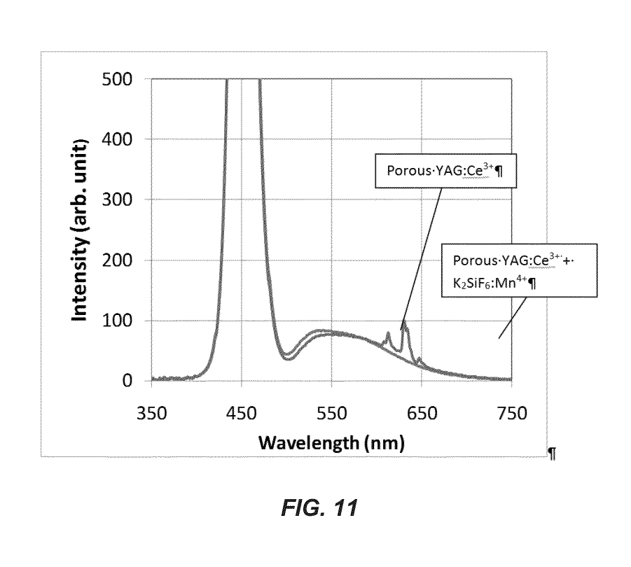

IQE and PL spectra measurement of porous YAG:Ce³⁺ with and without infiltration of K₂SiF₆:Mn⁴⁺ were performed with same instrument and setup as that in Example (5). The infiltrated porous YAG:Ce³⁺ gave a PL spectra with broad peak at 530 nm and emission lines in the wavelength range of 600 to 650 nm, which generated from YAG:Ce³⁺ and K₂SiF₆:Mn⁴⁺ respectively (FIG. 11). In contrast, porous YAG:Ce³⁺ ceramics without infiltration showed only a broad peak at 530 nm.

What is claimed is:

1. A method for fabricating a phosphor composite comprising:
depositing a fluoride phosphor out of a solution of the fluoride phosphor, wherein the solution of the fluoride phosphor is infiltrated within the pores of an interconnected porous ceramic matrix;
wherein the interconnected porous ceramic matrix is formed by heating a porous ceramic preform; and
wherein the porous ceramic preform is formed by the sublimation of an organic compound from a ceramic preform comprising the organic compound and at least one ceramic precursor.

2. The method of claim 1, wherein formation of the ceramic preform includes dissolving the organic compound in an organic solvent.

3. The method of claim 2, wherein formation of the ceramic preform includes crystallizing the dissolved organic compound within the preform.

4. The method of claim 3, wherein the porous ceramic preform comprises a cerium doped yttrium aluminum garnet as (Y₁₋ₓCeₓ)₃Al₅O₁₂, having Ce³⁺ ion concentration, x, in the range of about 0.01 to about 10 at %.

5. The method of claim 1, wherein the organic compound comprises camphene C₁₀H₁₆.

6. The method of claim 1, wherein the porous ceramic preform is annealed at about 450° C. to about 1600° C.

7. The method of claim 1, wherein the porous ceramic preform is sintered at about 1000° C. to about 2000° C.

8. The method of claim 7, wherein sintering of the porous ceramic preform is done at a heating rate of about 5° C./min.

9. The method of claim 7, wherein sintering of the porous ceramic preform is done at a cooling rate of about 10° C./min.

10. The method of claim 1, wherein the phosphor composite has a pore volume of about 10 to about 90%.

11. The method of claim 1, wherein the phosphor composite has pore size in the range of about 0.1 to about 1000 μm.

12. The method of claim 1, wherein the fluoride phosphor is a phosphor of the chemical formula A₂[MF₆]:Mn⁴⁺, and where A is selected from Li, Na, and K; and M is selected from Ge, Si, Sn, Ti, and Zr.

13. The method according claim 1 wherein the phosphor powder is loaded with the organic compound in an amount that is in the range of about 10 to 90 vol %.

14. A ceramic composite made according to the method of claim 1.

15. A ceramic composite comprising:
a porous garnet ceramic, defining a continuous porous network therein; and
a fluoride phosphor material disposed within said continuous porous network.

16. The ceramic composite of claim 15, wherein the porous ceramic comprises Y₃Al₅O₁₂.

17. The ceramic composite of claim 15, wherein the porous ceramic further comprises a dopant material.

18. The ceramic composite of claim 17, wherein the dopant material is Ce³⁺.

19. The ceramic composite of claim 18, wherein the fluoride phosphor material is A₂[MF₆]:Mn⁴⁺, A is Li, Na, or K; M is Ge, Si, Sn, Ti, or Zr.

20. The ceramic composite of claim 18, wherein the fluoride phosphor material is K₂SiF₆:Mn⁴⁺.

21. The ceramic composite of claim 15, wherein the fluoride phosphor material is disposed within pores of the continuous porous network.

22. The ceramic composite of claim 15, wherein the porous garnet ceramic is luminescent.

23. The ceramic composite of claim 21, wherein the fluoride phosphor material has an emissive peak at a higher wavelength than an emissive peak of the porous ceramic garnet.

24. The method of claim 1, wherein the interconnected porous ceramic matrix is formed by annealing then sintering the porous ceramic preform.
